(19) United States
(12) Patent Application Publication
(10) Pub. No.: US 2003/0233609 A1
(43) Pub. Date: Dec. 18, 2003

(54) Parallel error checking for multiple packets

(76) Inventors: Gus P. Ikonomopoulos, Austin, TX (US); Srinath Audityan, Austin, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/173,757

(22) Filed: Jun. 18, 2002

(51) Int. Cl. H03M 13/00

(52) U.S. Cl. 714/758

(57) ABSTRACT

Portions of error checking circuitry (90-95) are replicated so that the accumulated information (500) which is error checked in parallel may include any number of packets boundaries at any location. The location of packet boundaries, which may be information provided from system interconnect 16 for a receiver, is used to control routing (e.g. MUXes 70, 72) and the selection of one or more final checksum(s) (100-102). In one embodiment, CRC checker circuitry (30) uses multiple XOR trees (90-95) along with a system of controlled routing multiplexers (70, 72) and final_checksum select logic (96) to perform error checking on accumulated information which may include any number of packets boundaries at any location.

### FIELD OF THE INVENTION

The invention relates to error checking, and more particularly to parallel error checking for multiple packets.

### BACKGROUND OF THE INVENTION

Data processing systems have begun to use very high speed interconnect technology which uses differential signaling. The circuitry to implement this new high speed interconnect circuitry must be able to operate at very high frequencies, including frequencies which are often significantly higher than the frequencies used to operate other circuitry in the system. Other circuitry in the system often operates at lower frequencies in order to reduce power consumption.

The critical path for the circuitry used to implement this new high speed interconnect technology is often the error checking function. For example, a number of high speed interconnect protocols use CRC error checking. The transmitter side uses a CRC error checking algorithm to generate a packet checksum that is transferred along with a packet of information to the receiver side. The receiver side receives that packet checksum with the packet of information and uses the same CRC error checking algorithm to verify, with a know confidence level, that the received packet of information is the same as the one transmitted by the transmitter and that an error has not been introduced during transmission.

### BRIEF DESCRIPTION OF THE DRAWINGS

The present invention is illustrated by way of example and is not intended to be limited to the embodiment illustrated in the accompanying figures, in which like references indicate similar elements, and in which:

FIG. 1 illustrates, in block diagram form, a data processing system in accordance with one embodiment of the present invention;

FIG. 2 illustrates, in block diagram form, a portion of CRC checker 30 of FIG. 1 in accordance with one embodiment of the present invention;

FIG. 3 illustrates, in tabular form, operation of multiplexer (MUX) 70 of FIG. 2 in accordance with one embodiment of the present invention;

FIG. 4 illustrates, in tabular form, operation of MUX 72 of FIG. 2 in accordance with one embodiment of the present invention;

FIG. 5 illustrates, in tabular form, operation of final_checksum select logic 96 of FIG. 2 in accordance with one embodiment of the present invention;

FIG. 6 illustrates, in timing diagram form, timing information which is relevant to the circuit of FIG. 2 for a selected example.

FIG. 7 illustrates, in tabular form, packet boundary information which is relevant to the circuit of FIG. 2 for the selected example of FIG. 6.

FIG. 8 illustrates, in flow diagram form, a method for parallel error checking for multiple packets in accordance with one embodiment of the present invention; and

FIG. 9 illustrates, in flow diagram form, an expansion of a portion of the flow diagram of FIG. 8 in accordance with one embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION

Brackets are used to indicate one or more conductors within a plurality of conductors or the bit locations of a value. For example, “bus 60 [0-7]” or “conductors [0-7] of bus 60” indicates the eight higher order conductors of bus 60, and “address bits [0-7]” or “ADDRESS [0-7]” indicates the eight higher order bits of an address value.

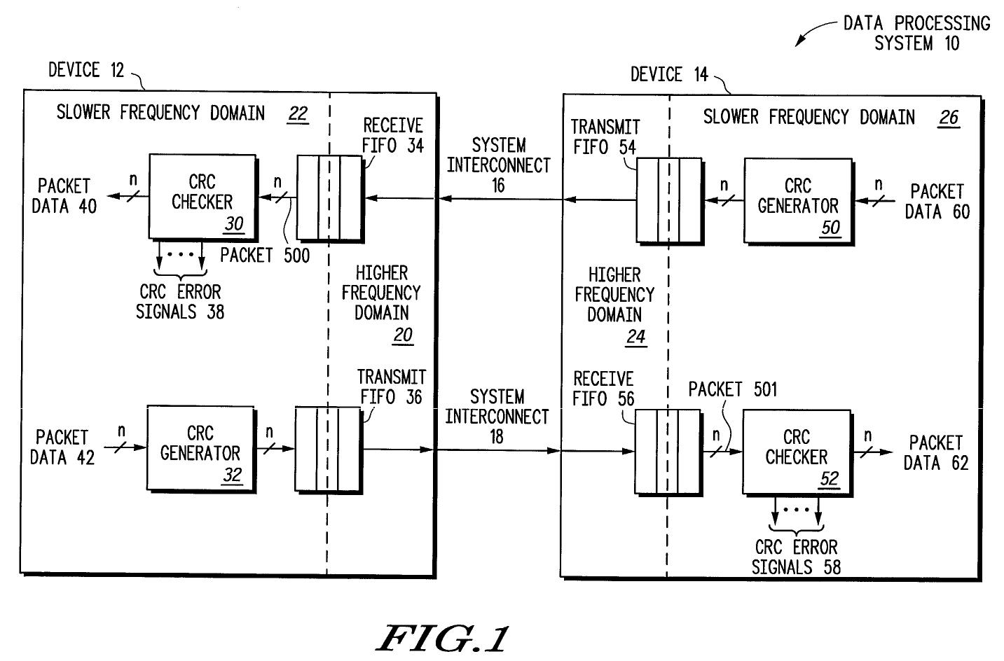

FIG. 1 illustrates, in block diagram form, a data processing system 10 in accordance with one embodiment of the present invention. In one embodiment, data processing system 10 includes device 12 and device 14 which are bi-directionally coupled by way of system interconnect conductors 16 and system interconnect conductors 18. In the embodiment of the present invention illustrated in FIG. 1, system interconnect 16 and 18 are unidirectional. Alternate embodiments of the present invention may instead use bi-directional conductors to interconnect devices 12 and 14.

In one embodiment of the present invention, device 12 and device 14 are separate integrated circuits (ICs) which are coupled together on an integrated circuits board by way of system interconnect 16 and 18. In alternate embodiments of the present invention, data processing system 10 may be implemented on a single integrated circuit. In yet other embodiments of the present invention, device 12 and device 14 may be located on different integrated circuit boards. Thus, data processing system 10 may be implemented in any manner as long as error checking is used on the information transferred between portions of the system (e.g. device 12 and device 14) by way of system interconnect (e.g. 16, 18).

Although the term “checksum” or “CRC checksum” is used through this document where a CRC error checking implementation is described, alternate embodiments of the present invention that used other error checking algorithms may produce an error result that is called a checksum or is called by some other name. A checksum is merely the name generally given to the error result produced by a CRC algorithm. The invention is applicable to any type of error checking algorithms.

Note that along with the checksum, the packet of information transferred across system interconnect 16 and 18 may include any information, including any combination of data, control, and status information. In some embodiments, the checksum itself may be part of the information which is included in the packet. Alternate embodiments may not include the checksum as part of the information which is included in the packet. System interconnect 16 and 18 may have any number of conductors, for implementing protocols that range from serial to highly parallel, which may or may not be time multiplexed to transfer packets of information and checksums. The present invention places no restriction on the number of conductors used by system interconnect 16 and 18, and no restriction on the protocol implemented by system interconnect 16 and 18, other than the mere fact that some type of error checking is used by the protocol.

In one embodiment of the present invention, packet data 60 is provided from another part, any part, of data processing system 10 to CRC generator 50. CRC generator 50 uses packet data 60 to generate a transmitted checksum. Both the transmitted checksum and packet data 60 are then provided to transmit FIFO (first in first out) 54. Different embodiments of the present invention may use any desired depth of transmit FIFO 54. Packet data 60 and the transmitted checksum are then transmitted to device 12 by way of system interconnect 16. Receive FIFO 34 is coupled to system interconnect 16 to receive and store the information received from device 14, namely a plurality of packets, where each packet includes packet data 60 and its corresponding transmitted checksum. Receive FIFO 34 then provides this stored packet information 500 to CRC checker circuitry 30 using a predetermined accumulation width “n”, where n is any positive integer number of bits. Note that CRC Checker 30 receives n-bit wide packet information 500 which may have one or more packet boundaries in it. CRC checker 30 uses the n-bit wide packet information 500 to produce one or more CRC error signals 38 which can be used to indicate that an error has been detected.

Higher frequency domain circuitry 20 is used to interface between system interconnect 16, which operates at a high frequency also, and receive FIFO 34. If the CRC checker circuitry 30 is located in higher frequency domain circuitry 20 and is operated at this higher frequency, then the CRC checker circuitry will consume more power and must be more heavily pipelined in order to perform a CRC check on each separate packet as it is received. However, alternate embodiments of the present invention may locate the CRC checker 30 as part of the higher frequency domain circuitry 20 and may operate the CRC checker at this higher frequency.

If the CRC checker 30 is implemented as part of the slower frequency domain circuitry 22, and thus is operated at a frequency slower than that used to operate circuitry 20, receive FIFO 34 is needed to store incoming packets from system interconnect 16 until CRC checker 30 is available to process these incoming packets. In order to keep CRC checker 30 from slowing down the transmission rate of system interconnect 16, CRC checker 30 should be able to operate on multiple packets simultaneously, thus in parallel.

The above discussion for the device 14 to device 12 transmission is also applicable for the device 12 to device 14 transmission. Thus, in one embodiment of the present invention, packet data 42 is provided from another part, any part, of data processing system 10 to CRC generator 32. CRC generator 32 uses packet data 42 to generate a transmitted checksum. Both the transmitted checksum and packet data 42 are then provided to transmit FIFO (first in first out) 36. Different embodiments of the present invention may use any desired depth of transmit FIFO 36. Packet data 42 and the transmitted checksum are then transmitted to device 14 by way of system interconnect 18. Receive FIFO 56 is coupled to system interconnect 18 to receive and store the information received from device 12, namely a plurality of packets, where each packet includes packet data 42 and its corresponding transmitted checksum. Receive FIFO 56 then provides this stored packet information 501 to CRC checker circuitry 52 using a predetermined accumulation width “n”, where n is any positive integer number of bits. Note that CRC Checker 52 receives n-bit wide packet information 501 which may have one or more packet boundaries in it. CRC checker 52 uses the n-bit wide packet information 501 to produce one or more CRC error signals 58 which can be used to indicate that an error has been detected.

Higher frequency domain circuitry 24 is used to interface between system interconnect 18, which operates at a high frequency also, and receive FIFO 56. If the CRC checker circuitry 52 is located in higher frequency domain circuitry 24 and is operated at this higher frequency, then the CRC checker circuitry will consume more power and must be more heavily pipelined in order to perform a CRC check on each separate packet as it is received. However, alternate embodiments of the present invention may locate the CRC checker 52 as part of the higher frequency domain circuitry 24 and may operate the CRC checker at this higher frequency.

If the CRC checker 52 is implemented as part of the slower frequency domain circuitry 26, and thus is operated at a frequency slower than that used to operate circuitry 24, receive FIFO 56 is needed to store incoming packets from system interconnect 18 until CRC checker 52 is available to process these incoming packets. In order to keep CRC checker 52 from slowing down the transmission rate of system interconnect 18, CRC checker 52 should be able to operate on multiple packets simultaneously, thus in parallel.

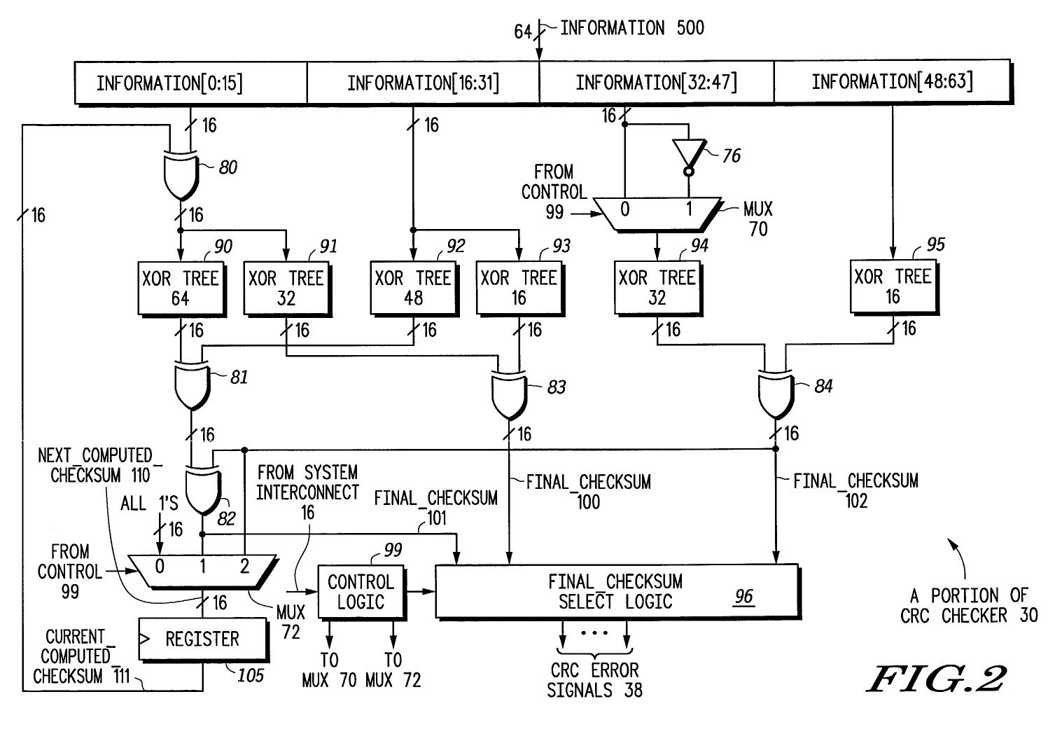

FIGS. 2-7 illustrate one possible embodiment of a portion of CRC checker 30 of FIG. 1. Although the present invention applies to any number of packet boundaries and any location of those boundaries with the accumulated information processed in parallel by the CRC checker 30, the illustrated embodiment assumes the following: (1) that the error checking algorithm is a CRC algorithm (2) that the packet width must be a multiple of 32 bits; (3) that the width of the accumulated information is 64 bits; and (4) that the checksum width is 16 bits. Alternate embodiments of the present invention may use any error-checking algorithm, not just CRC algorithms. For example, the present invention may be used with ECC (error checking and correction), parity etc. The packet width may be any width, but is usually selected to be a multiple of the checksum width to reduce the circuitry required for implementation. The width of the accumulated information may be any width, but is usually selected to be a multiple of the checksum width to reduce the circuitry required for implementation. The checksum width is usually determined by the system interconnect protocol and affects the probability that a transmission error will go undetected. In general, the more bits in the checksum, the lower the probability that a transmission error will go undetected.

For the purposes of explaining the illustrated embodiment, it will be assumed that CRC checks are performed on packets. A packet is comprised of three components: header, data, and checksum. The header contains control information defined by the protocol. The data is the information intended for transmission. The checksum is the result of CRC computation on the header and data of the packet. Note, however, that the present invention is in no way limited to this configuration of information.

In FIG. 2, information[0:63] 500 is composed of one of the following: (1) information[0:31] 500 is either the end of a packet larger than 32-bits that started earlier or a complete packet that is 32 bits in size, and information[32:63] 500 is either the beginning of a new packet larger than 32-bits or a complete packet that is 32 bits in size; or (2) information[0:63] 500 is either the beginning of a packet larger than 64-bits, the middle of a packet larger than 64-bits, the end of a packet larger than 64-bits, or a complete packet that is 64-bits in size. In addition to information[0:63] 500, some embodiments of the present invention may include two extra bits (not shown) which may be used for a variety of purposes, such as, for example, indicating the boundaries of the packets.

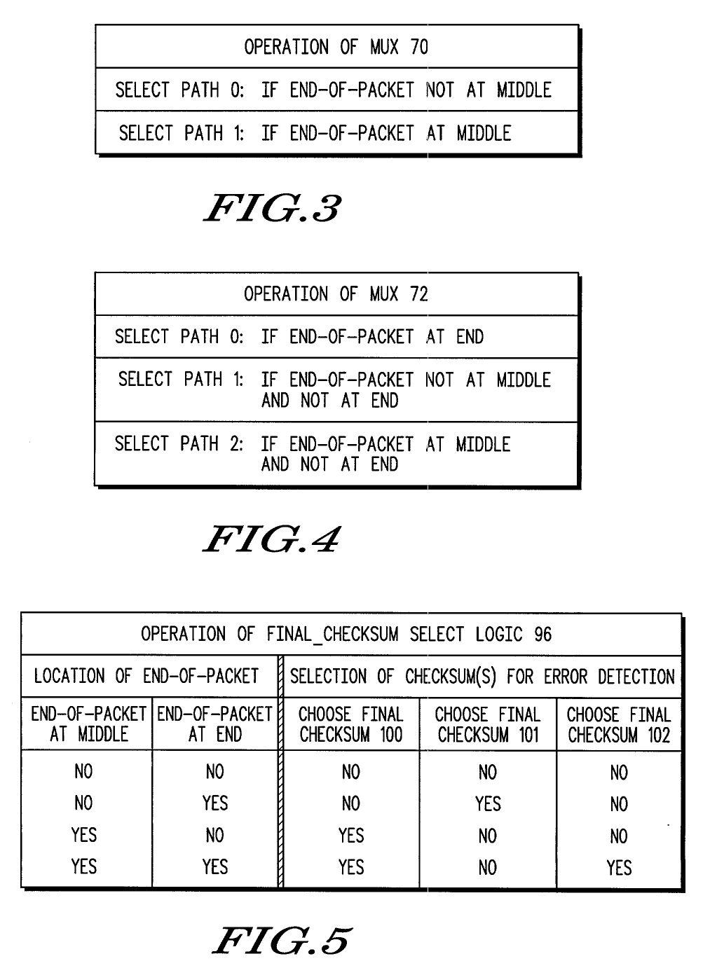

One embodiment of the control logic required for MUX 70 (see FIG. 2) is described in FIG. 3. Alternate embodiments of the present invention may use different control logic to control MUX 70. If a packet ends at information[0:31] 500, path 1 will be selected, otherwise path 0 will be selected. Path 1 is equivalent to initializing the checksum for CRC calculation on the packet starting at information[32:63] 500. Path 0 is equivalent to continuing the CRC calculation from information[0:31] 500 to information[32:63] 500.

One embodiment of the control logic required for MUX 72 (see FIG. 2) is described in FIG. 4. Alternate embodiments of the present invention may use different control logic to control MUX 72. If a packet ends at information[0:31] 500 and the following packet does not end at information[32:63] 500, path 2 will be selected. If a packet does not end either at information[0:31] 500 or at information[32:63] 500, path 1 will be selected. If a packet ends at information[32:63] 500, path 0 will be selected. MUX 72 selects the next_computed_checksum 110. Path 2 is the checksum calculated on a packet starting at information[32:63] 500, which continues into the next information[0:31] 500. Path 1 is the checksum calculated on a packet spanning all of information[0:63] 500, which continues into the next information[0:31] 500. Path 0 is the initial checksum, all is to be used for the CRC computation on the following packet arriving in the next information[0:31] 500.

Two algorithm trees exist in FIG. 2. The first algorithm tree (64-bit algorithm tree), which performs parallel CRC computation on 64 bits of information[0:63] 500 and uses the current_computed_checksum 111, consists of xor gate 80, xor gate 81, xor gate 84, xor gate 82, and the following sub-algorithm trees: (1) xor_tree_{—}64 90, (2) xor_tree_{—}48 92, (3) xor_tree_{—}32 94, and (4) xor_tree_{—}16 95. The second algorithm tree (32-bit algorithm tree), which performs parallel CRC computation on 32 bits of information[0:63] 500 and uses the current_computed_checksum 111, consists of xor gate 80, xor gate 83, and the following sub-algorithm trees: (1) xor_tree_{—}32 91 (identical to xor_tree_{—}32 94) and (2) xor_tree_{—}16 93 (identical to xor_tree_{—}16 95). Because the algorithm trees are broken up into xor gates and sub-algorithm trees, they can be combined to form other algorithm trees. For example, inverter gate 76, xor gate 84, and the following sub-algorithm trees: (1) xor_tree_{—}32 94 and (2) xor_tree_{—}16 95 form another 32-bit algorithm tree. In the embodiment of the present invention illustrated in FIG. 2, at any one time either the 64-bit algorithm tree or the two 32-bit algorithm trees will be used. Alternate embodiments of the present invention may use any combination of algorithm trees in the illustrated manner.

In one embodiment of the present invention, register 105, illustrated in FIG. 2, contains the current computed_checksum 111 which is to be used in the CRC computation of information[0:63] 500. It captures and stores the next computed checksum 110 from MUX 72. Alternate embodiments of the present invention may store the next_computed checksum 110 in any manner.

The final_checksum_select_logic 96, illustrated in FIG. 2, selects one of the following final_checksums to check, which is done only at the end of a packet: (1) final_checksum 101, (2) final_checksum 100, and (3) final_checksum 102. FIG. 5 indicates the final_checksum(s) to be used for CRC error(s) checking in the embodiment of the present invention illustrated in FIG. 2. If a packet does not end in information[0:31] 500 or information[32:63] 500, none of the final_checksums are checked. If a packet does not end in information[0:31] 500 and ends in information[32:63] 500, final_checksum 101 will be checked. If a packet ends in information[0:31] 500 and not at information[32:63] 500, final_checksum 100 will be checked. If a packet ends in information[0:31] 500 and the following packet ends at information[32:63] 500, both final_checksum 100 (for the first packet) and final_checksum 102 (for the following packet) will be checked. The checksum of a packet is part of the packet and will be present within information[0:63] 500 as already stated. In one embodiment of the present invention, CRC checker 30 can treat the CRC checksum that is present in the packet as data. This way a non-zero final checksum at the end of CRC computation on a packet indicates a CRC error and no error otherwise.

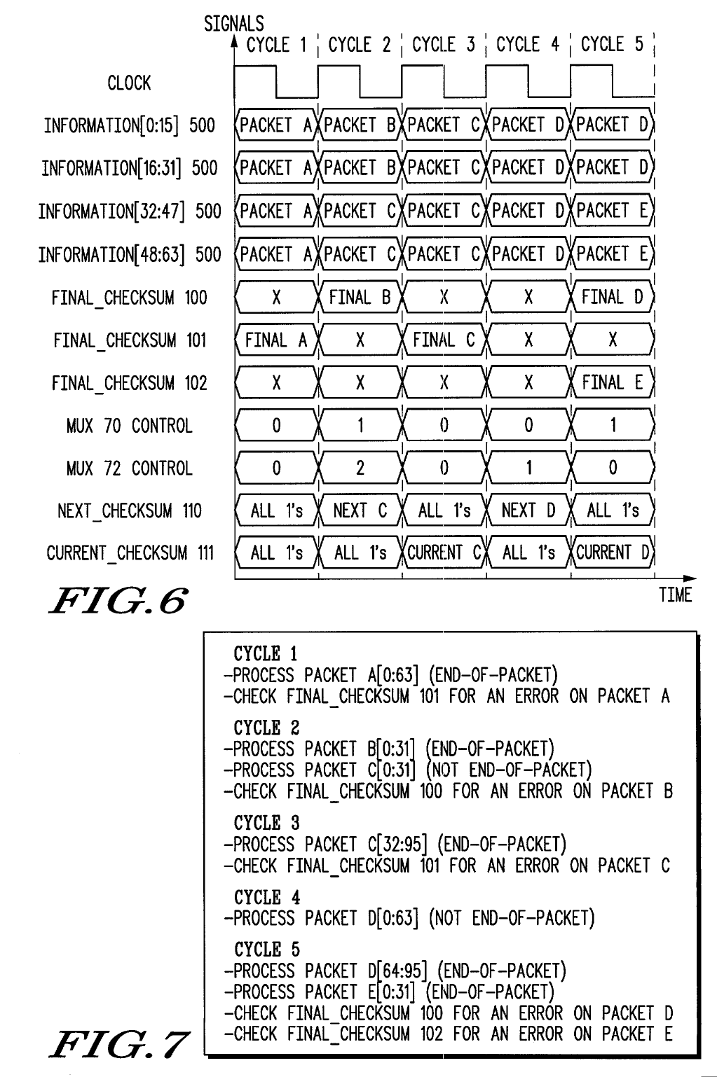

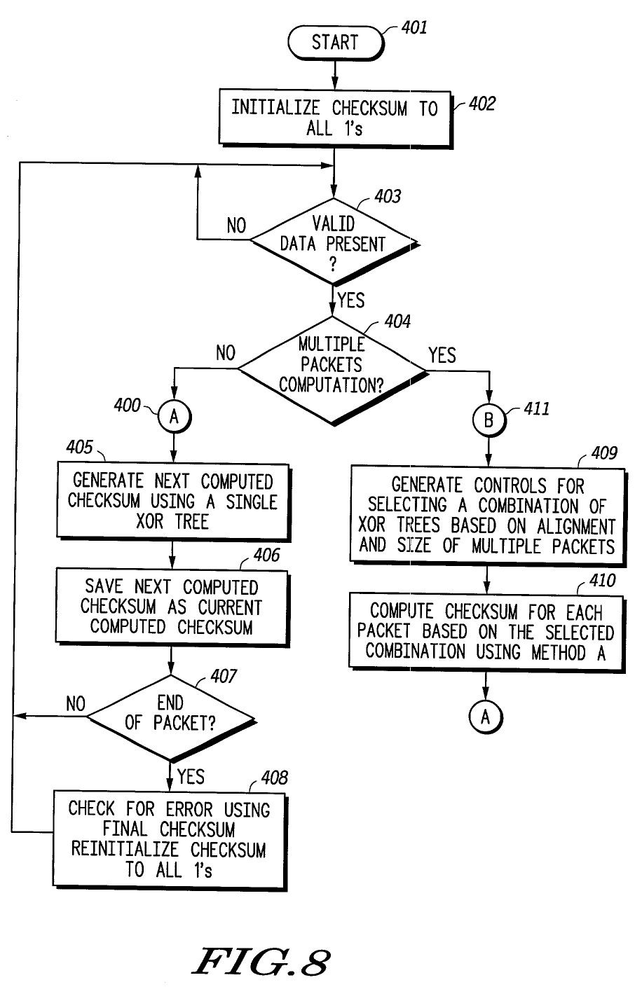

FIG. 6 is a timing diagram illustrating the operation of the CRC checker 30, shown in FIG. 2. In FIG. 6, an “X” is used to indicate a that the value is a “don't care”. FIG. 7 describes the events occurring on each cycle of the timing diagram in FIG. 6. FIG. 6 illustrates 5 cycles of operation with information from 5 packets of differing sizes. The packets are labeled A, B, C, D and E. Packet A is 64-bits in size, packet B is 32-bits in size, packet C is 96-bits in size, packet D is 96-bits in size, and packet E is 32-bits in size. The current computed_checksum is initialized to all 1s at start-up.

In cycle 1, all 64 bits of information[0:63] 500 are composed of packet A, which begins with information[0:31] 500 and ends with information[32:63] 500 (64-bit packet). MUX 70 will select path 0, since all 64 bits of information[0:63] 500 belong to the same packet. MUX 72 will select path 0, assigning next_computed_checksum 110 to all 1s. The final_checksum 101 will be checked as the final checksum of packet A. If final_checksum 101 is non-zero, a CRC error will be indicated with crc_error 38, indicating a CRC error on packet A.

In cycle 2, information[0:31] 500 contains all of packet B and information[32:63] contains the start of packet C. MUX 70 will select path 1, which will choose the output of inverter 76. Inverter 76 is equivalent to an xor of 16 bits with all 1s (the initial current_computed_checksum 111 value). MUX 72 will select path 2, assigning next_computed_checksum 110 to the output of xor 84. The final_checksum 100 will be checked as the final checksum of packet B. If final_checksum 100 is non-zero, a CRC error will be indicated with crc_error 38, indicating a CRC error packet B.

In cycle 3, all 64 bits of information[0:63] 500 are composed of the end of packet C. MUX 70 will select path 0, since all 64 bits of information[0:63] 500 belong to the same packet. MUX 72 will select path 0, assigning next_computed_checksum 110 to all is. The final_checksum 101 will be checked as the final checksum of packet C. If final_checksum 101 is non-zero, a CRC error will be indicated with crc error 38, indicating a CRC error on packet C.

In cycle 4, all 64 bits of information[0:63] 500 are composed of the start of packet D. MUX 70 will select path 0, since all 64 bits of information[0:63] 500 belong to the same packet. MUX 72 will select path 1, assigning next_computed_checksum 110 to the output of xor gate 82. Since packet D did not end, none of the final_checksums will be checked.

In cycle 5, information[0:31] 500 contains the end of packet D and information[32:63] contains all of packet E. MUX 70 will select path 1, which will choose the output of inverter 76. Inverter 76 is equivalent to an xor of 16 bits with all 1s (the initial current_computed_checksum 111 value). MUX 72 will select path 0, assigning next_computed_checksum 110 to all 1s. The final_checksum 100 will be checked as the final checksum of packet D. If final_checksum 100 is non-zero, a CRC error will be indicated with crc_error 38, indicating a CRC error packet D. The final_checksum 102 will be checked as the final checksum of packet E. If final_checksum 100 is non-zero, a CRC error will be indicated with crc_error 38, indicating a CRC error packet E.

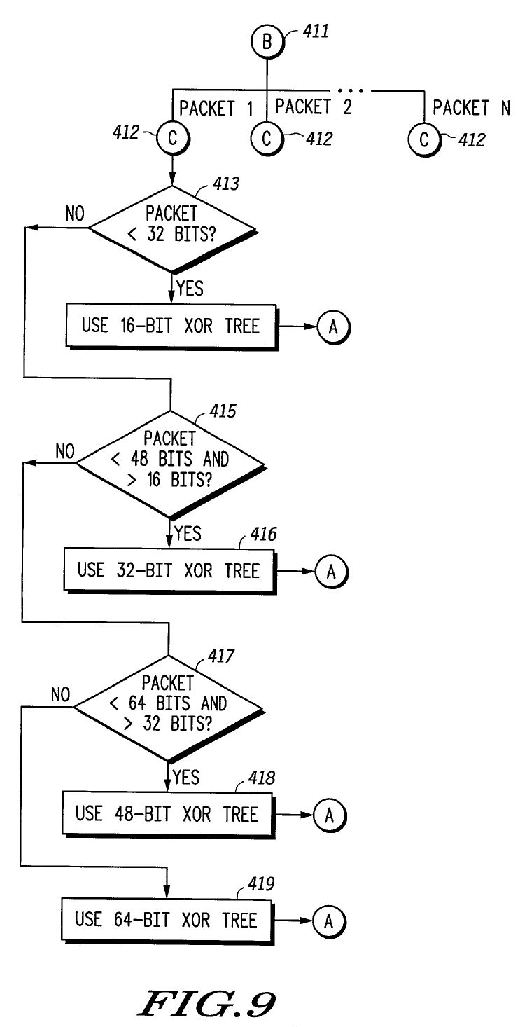

FIG. 8 illustrates, in flow diagram form, a method for parallel error checking for multiple packets in accordance with one embodiment of the present invention. The flow starts at oval 401. From oval 401, the flow continues at step 402 where the checksum is initialized to all ones. Note that alternate embodiments of the present invention may use other values besides all ones, depending upon the error correction algorithm that is being used.

From step 402, the flow continues to decision diamond 403 where the question is asked “is valid data present?”. If valid data is not present, the flow continues back to the beginning of decision diamond 403 and remains in this loop until valid data has been received and is present. If valid data is present, the flow continues from decision diamond 403 to decision diamond 404 where the question is asked “does the computation involve multiple packets?”. If the computation does involve multiple packets, then the flow continues to circle B 411 and then to step 409 where controls are generated to select a combination of error checking algorithms, in one embodiment, a combination of XOR trees based on the alignment and size of the multiple packets involved in the computation. The flow continues from step 409 to step 410 where the checksum is computed for each packet involved based on the selected combination from step 409. The flow continues from step 410 to circle A 400 for each packet. From decision diamond 404, the flow continues to circle A 400 if the computation does not involve multiple packets.

From circle A 400, the flow continues to step 405 where the next checksum is computed using the error checking algorithm, in this case, a single XOR tree. The flow continues to step 406 where the next checksum that was computed in step 405 is saved off for further computations if necessary. This also becomes the final checksum if further computations are not necessary and the end of packet has been reached. From step 406, the flow continues to decision diamond 407 where the question is asked “has the end of the packet been reached?”. If the end of packet has not been reached, the flow continues to decision diamond 403. If the end of packet has been reached, the flow continues to step 408 where an error check is performed using the final checksum and the checksum received along with the packet (transmitted checksum) to detect an error. Also the checksum in reinitialized to all ones. The flow continues from step 408 to decision diamond 403.

FIG. 9 illustrates, in flow diagram form, an expansion of steps 409 and 410 of the flow diagram of FIG. 8 in accordance with one embodiment of the present invention. The flow starts at circle B 411. From circle B 411, the flow continues to circle C 412 for each individual packet involved in the computation. The flow continues from circle C 412 to decision diamond 413 where the question is asked “is the packet size smaller than 32 bits?”. If the packet size is smaller than 32 bits, the flow continues to step 414 where a decision is made to use a 16-bit XOR tree.

The flow continues from step 414 to circle A 400. If the packet size is larger than 32 bits, the flow continues to decision diamond 415 where the question is asked “is the packet size greater than 16-bits and smaller than 48-bits?”. If the packet size is greater than 16-bits and smaller than 48-bits, the flow continues to step 416 where a decision is made to use a 32-bit XOR tree.

The flow continues from step 416 to circle A 400. If the packet size is not greater than 16-bits and smaller than 48-bits, then the flow continues to decision diamond 417 where the question is asked “is the packet size greater than 32-bits and smaller than 64-bits?”. If the packet size is greater than 32 bits and smaller than 64-bits, the flow continues to step 418 where a decision is made to use a 48-bit XOR tree.

The flow continues from step 418 to circle A 400. If the packet size is not greater than 32-bits and smaller than 64-bits, the flow continues to step 419 where a decision is made to use a 64-bit XOR tree. The flow continues from step 419 to circle A 400.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a nonexclusive inclusion, such that a process, method, article, or apparatus that comprises a list of elements does not include only those elements but may include other elements not expressly listed or inherent to such process, method, article, or apparatus.

1. A method of simultaneously checking for errors in a plurality of packets comprising:
routing the plurality of packets through a plurality of algorithm trees;
determining a corresponding error result for each packet of the plurality of packets;
detecting and finally checking any ending packets of the plurality of packets; and
detecting and maintaining the corresponding error result of a continuing packet of the plurality of packets.

2. The method of claim 1 wherein one of the plurality of algorithm trees represents a smallest allowed packet size.

3. The method of claim 1 wherein one of the plurality of packets is a portion of a subsequent packet.

4. The method of claim 2 wherein the one of the plurality of algorithm trees representing the smallest allowed packet size is made from a combination of a plurality of sub-algorithm trees.

5. The method of claim 1 wherein the corresponding error result is a CRC checksum.

6. The method of claim 1 further comprising providing a computed error result to each of the plurality of algorithm trees.

7. The method of claim 6 wherein the computed error result is an optimized initialization value.

8. The method of claim 6 wherein the computed error result is the corresponding error result of the continuing packet.

9. The method of claim 1 further comprising accumulating the plurality of packets into a parallel buffer.

10. The method of claim 1 wherein detecting and finally checking any ending packets comprises identifying ending packets by an associated control data.

11. The method of claim 10 wherein the associated control data is transmitted via a distinct interface from the plurality of packets.

12. The method of claim 6 wherein determining the corresponding error result comprises combining the computed error result with a corresponding data contained in the packet.

13. The method of claim 1 wherein each of the plurality of packets include a data and a transmitted checksum.

14. The method of claim 13 wherein finally checking comprises determining if the corresponding error result equals zero.

15. The method of claim 1 wherein finally checking comprises determining if a transmitted checksum separated from each of the plurality of packets is equal to the corresponding error result.

16. A method of simultaneously creating a checksum for a plurality of data packets comprising:
routing the plurality of data packets through a plurality of algorithm trees;
determining a corresponding checksum for each packet of the plurality of data packets;
detecting and finally creating checksums for any ending data packets of the plurality of data packets; and
detecting and maintaining a partial checksum of a continuing data packet of the plurality of packets.

17. The method of claim 16 wherein each checksum that is finally created is attached to its corresponding data packet.

18. An error checking circuit comprising:
a means for receiving an N-wide collection of information;
a means for calculating a plurality of error values for a portion of the N-wide collection of information;
a means for generating a selected error value by selecting one of the plurality of error values when an end of packet is detected and selecting another of the plurality of error values when an end of packet is not detected; and
a means for calculating a final error value or a continuing error value by combining a current error value with the selected error value.

19. The error checking circuit of claim 18, wherein N is an integer multiple of M and all error values are calculated as an M wide value, and further wherein each of the means for generating a selected error value is an XOR tree of size determined as an integer multiple of M.

20. An error checking circuit comprising:
an N-wide bus;
a plurality of XOR trees receiving N-wide information from the N-wide bus and generating a plurality of error values for a portion of the N-wide information; and
control logic receiving the plurality of error values, a current error value and portions of the N-wide information, calculating a plurality of possible error results, and generating a final error value or a continuing error value, wherein the current error value is a predetermined error value or a previously determined continuing error value.
